(19) United States
(12) Patent Application Publication
(10) Pub. No.: US 2016/0271835 A1
(43) Pub. Date: Sep. 22, 2016

(54) CUTTING APPARATUS

(71) Applicant: DISCO CORPORATION, Tokyo (JP)

(72) Inventors: Takuya Kato, Tokyo (JP); Takeomi Fukuoka, Tokyo (JP)

(21) Appl. No.: 15/072,679

(22) Filed: Mar. 17, 2016

(30) Foreign Application Priority Data
Mar. 18, 2015 (JP) 2015-054771

(51) Int. Cl. B28D 5/02; B28D 5/00; H01L 21/67; B23Q 11/08

(52) U.S. Cl. CPC B28D 5/024; B23Q 11/0816; B28D 5/0076; H01L 21/67092

(57) ABSTRACT

A cutting apparatus includes a holding table for holding a workpiece, a feeding unit for moving the holding table in a feeding direction, first and second bellows connected to opposite ends of the holding table in the feeding direction, each of the bellows having an upper wall and opposite side walls adapted to be expanded and contracted for covering the feeding unit, a pair of drain channels provided along the sides of both bellows for receiving cutting water used in cutting the workpiece, and a scrap receptacle provided at the downstream end of the first bellows in the feeding direction for receiving scraps generated from the workpiece in cutting the workpiece. The cutting apparatus further includes a pair of fall prevention plates provided along the pair of drain channels for preventing scraps scattered onto the upper wall of the first bellows from falling into the drain channels.

### BACKGROUND OF THE INVENTION

1. Field of the Invention

The present invention relates to a cutting apparatus for cutting a workpiece such as a chip size package (CSP) substrate obtained by packaging semiconductor chips.

2. Description of the Related Art

In a semiconductor device fabrication process, a plurality of crossing division lines called streets are formed on the front side of a substantially disk-shaped semiconductor wafer to thereby define a plurality of separate regions where a plurality of circuits (devices) such as ICs and LSIs are formed. The semiconductor wafer thus having the devices is cut along the division lines to thereby obtain individual semiconductor chips. These semiconductor chips are packaged to be widely used in electric equipment such as mobile phones and personal computers.

A further reduction in size and weight of such electric equipment is desired and there has been developed a packaging technique capable of reducing the size of a semiconductor device package, called chip size package (CSP). As one of the CSP techniques, a packaging technique called quad flat non-lead package (QFN) has been put into practical use. This packaging technique called QFN is such that a plurality of semiconductor chips are arranged like a matrix on a metal plate such as a copper plate so as to be partitioned by a plurality of streets, the metal plate having a plurality of connection terminals corresponding to the connection terminals of the semiconductor chips. Further, the semiconductor chips are molded with resin from the back side to thereby form a resin portion for integrating the metal plate and the semiconductor chips, thus forming a CSP substrate. This CSP substrate is cut along the streets to obtain the individual chip size packages (CSPs) divided from each other.

In general, cutting of the CSP substrate is performed by a cutting apparatus. This cutting apparatus includes a holding table for holding a workpiece, cutting means having a cutting blade for cutting the workpiece held on the holding table, cutting water supplying means for supplying a cutting water to a cutting area where the workpiece is cut by the cutting blade, feeding means for moving the holding table in a feeding direction, a first bellows connected at one end thereof to one end of the holding table in the feeding direction for covering the feeding means, a second bellows connected at one end thereof to the other end of the holding table in the feeding direction for covering the feeding means, a pair of drain channels provided along both sides of the first and second bellows so as to extend in the feeding direction, for receiving the cutting water used in cutting the workpiece, and a scrap receptacle provided at the downstream ends of the drain channels and the first bellows for receiving scraps generated from the workpiece in cutting the workpiece as well as the cutting water containing cutting dust, whereby cutting is not hindered by the scraps of the CSP substrate (see Japanese Patent Laid-Open No. 2004-186361, for example).

### SUMMARY OF THE INVENTION

However, when the scraps generated from the workpiece in cutting the workpiece falls into the drain channels from the first bellows and they are accumulated in the drain channels, there arises a problem such that the cutting water may stay in the drain channels and finally overflow from the drain channels to contaminate the inside of the cutting apparatus.

It is therefore an object of the present invention to provide a cutting apparatus which can prevent that the scraps generated from the workpiece in cutting the workpiece and scattered onto the first bellows may fall into the drain channels provided on both sides of the first bellows.

In accordance with an aspect of the present invention, there is provided a cutting apparatus including a holding table for holding a workpiece, cutting means having a cutting blade for cutting the workpiece held on the holding table, cutting water supplying means for supplying a cutting water to a cutting area where the workpiece is cut by the cutting blade, feeding means for moving the holding table in a feeding direction, indexing means for moving the cutting means in an indexing direction perpendicular to the feeding direction, a first bellows connected at one end thereof to one end of the holding table in the feeding direction, the first bellows having an upper wall and opposite side walls adapted to be expanded and contracted for covering the feeding means, a second bellows connected at one end thereof to the other end of the holding table in the feeding direction, the second bellows having an upper wall and opposite side walls adapted to be expanded and contracted for covering the feeding means, a pair of drain channels provided on both sides of the first and second bellows in the indexing direction for receiving the cutting water supplied to the cutting area by the cutting water supplying means in cutting the workpiece, a scrap receptacle provided at the other end of the first bellows in the feeding direction for receiving scraps generated from the workpiece in cutting the workpiece, and a pair of fall prevention plates provided along the pair of drain channels for preventing that the scraps scattered onto the upper wall of the first bellows in cutting the workpiece may fall into the drain channels.

Preferably, the fall prevention plates are formed of fluororesin.

The cutting apparatus of the present invention includes the pair of fall prevention plates provided along the pair of drain channels for preventing that the scraps scattered onto the upper wall of the first bellows in cutting the workpiece may fall into the drain channels. Accordingly, the scraps scattered above the drain channels in cutting the workpiece with the cutting blade can be received by the fall prevention plates. Further, the scraps scattered onto the upper wall of the first bellows and moved toward the drain channels can be received by the fall prevention plates. That is, all of the scraps thus scattered can be prevented from falling into the drain channels by the provision of the fall prevention plates, so that it is possible to solve the problem that the cutting water may stay in the drain channels due to the accumulation of the scraps in the drain channels, and as a result the cutting water may overflow from the drain channels to contaminate the inside of the cutting apparatus.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a cutting apparatus according to a preferred embodiment of the present invention;

FIG. 2 is a perspective view of a holding table, a first bellows, and a second bellows included in the cutting apparatus shown in FIG. 1;

FIG. 3 is an exploded perspective view similar to FIG. 2, showing the arrangement of fall prevention plates;

FIG. 4A is an enlarged sectional view of an essential part, showing an expanded condition of the first bellows shown in FIG. 2;

FIG. 4B is a view similar to FIG. 4A, showing a contracted condition of the first bellows;

FIG. 5A is a perspective view of a package substrate as a workpiece in the preferred embodiment;

FIG. 5B is a sectional view of the package substrate shown in FIG. 5A;

FIGS. 6A and 6B are schematic side views for illustrating a cutting step to be performed by the cutting apparatus shown in FIG. 1; and

FIG. 7 is a perspective view showing a condition that the package substrate is divided into individual devices by performing the cutting step shown in FIG. 6.

### DETAILED DESCRIPTION OF THE PREFERRED EMBODIMENT

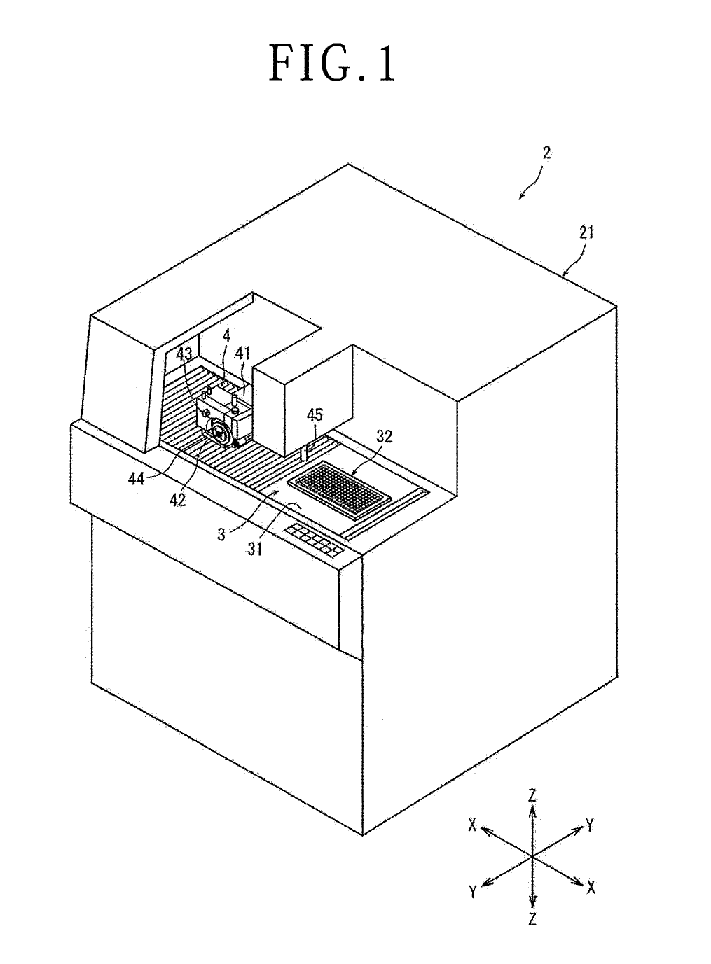

A preferred embodiment of the cutting apparatus according to the present invention will now be described in detail with reference to the attached drawings. FIG. 1 is a perspective view of a cutting apparatus according to the preferred embodiment. A cutting apparatus 2 shown in FIG. 1 includes a substantially box-shaped housing 21. The housing 21 is provided with a holding table (chuck table) 3 as workpiece holding means for holding a workpiece. The holding table 3 is movable in a work feeding direction (X direction) shown by an arrow X. The holding table 3 is composed of a rectangular table body 31 and a vacuum chuck 32 provided on the table body 31. The vacuum chuck 32 includes a plurality of crossing escape grooves corresponding to a plurality of crossing division lines of a package substrate as a plate-like workpiece to be hereinafter described, for allowing the escape of a cutting edge of a cutting blade to be hereinafter described. The vacuum chuck 32 further includes a plurality of suction holes formed in a plurality of separate regions defined by the plural escape grooves mentioned above. These suction holes of the vacuum chuck 32 are in communication with suction means (not shown). The holding table 3 is movable in the X direction by work feeding means (X moving means or work feeding mechanism) (not shown). The holding table 3 is also rotatable by a rotating mechanism (not shown).

The cutting apparatus 2 shown in FIG. 1 further includes a spindle unit 4 as cutting means. The spindle unit 4 is movable in an indexing direction (Y direction) shown by an arrow Y perpendicular to the X direction by indexing means (Y moving means or indexing mechanism) (not shown) and also movable in a cutter feeding direction (Z direction) shown by an arrow Z perpendicular to both the X direction and the Y direction by cutter feeding means (Z moving means or cutter feeding mechanism) (not shown). The spindle unit 4 as the cutting means includes a spindle housing 41, a rotating spindle 42 rotatably supported to the spindle housing 41, and a cutting blade 43 mounted on the front end portion of the rotating spindle 42 and having a peripheral cutting edge. The spindle housing 41 is mounted on a movable base (not shown) and movable for adjustment in the Y direction and the Z direction. The spindle unit 4 as the cutting means further includes a cutting water nozzle 44 for supplying a cutting water to a cutting area where the workpiece is cut by the cutting blade 43. The cutting water nozzle 44 is connected to cutting water supplying means (not shown).

The cutting apparatus 2 further includes imaging means (imaging unit) 45 for imaging the surface of the workpiece held on the holding table 3 to detect an area to be cut by the cutting blade 43. The imaging means 45 includes an optical system such as a microscope and an imaging device (CCD). An image signal obtained by the imaging means 45 is sent to control means (controller) (not shown).

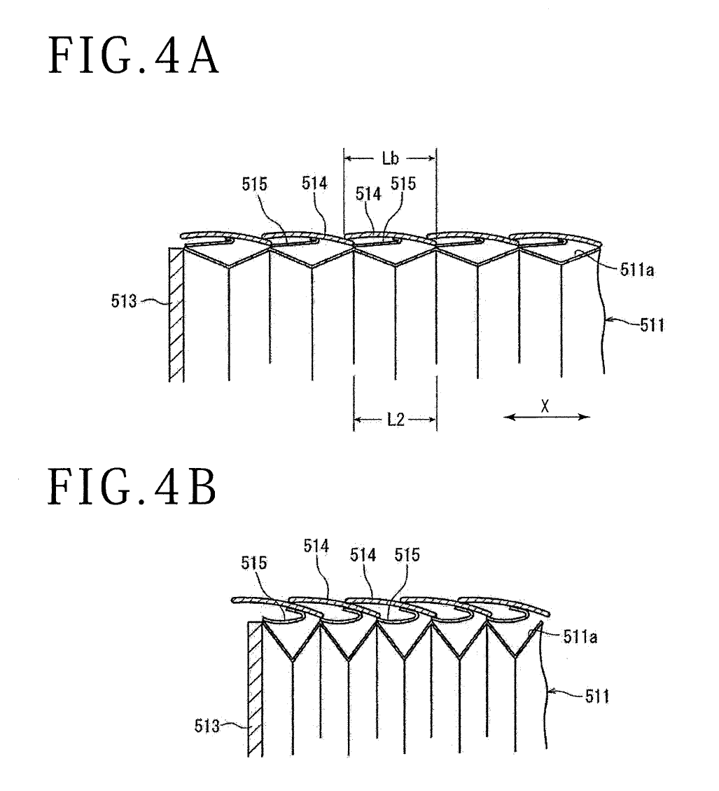

Referring to FIGS. 1, 2, and 3, a first bellows 51 and a second bellows 52 are provided on both sides of the holding table 3 in the X direction, so as to cover the X moving means (not shown) for moving the holding table 3 in the X direction. The first bellows 51 is composed of a bellows member 511 adapted to be expanded and contracted, a pair of connecting members 512 and 513 mounted on both ends of the bellows member 511 in the X direction, a plurality of protective plate members 514 for covering the upper surface of the bellows member 511, and a plurality of protective film members 515 (see FIGS. 4A and 4B) provided between the plural protective plate members 514 and the bellows member 511. The bellows member 511 is formed from a foldable sheet member like a cloth so as to have a plurality of alternate ridges and grooves. The bellows member 511 has an upper wall 511a and a pair of opposite side walls 511b connected to the upper wall 511a. Each of the connecting members 512 and 513 may be formed from a metal plate. The first bellows 51 configured above is mounted in such a manner that the connecting member 512 is connected to one end surface of the holding table 3 and the connecting member 513 is connected to a stationary member to be hereinafter described.

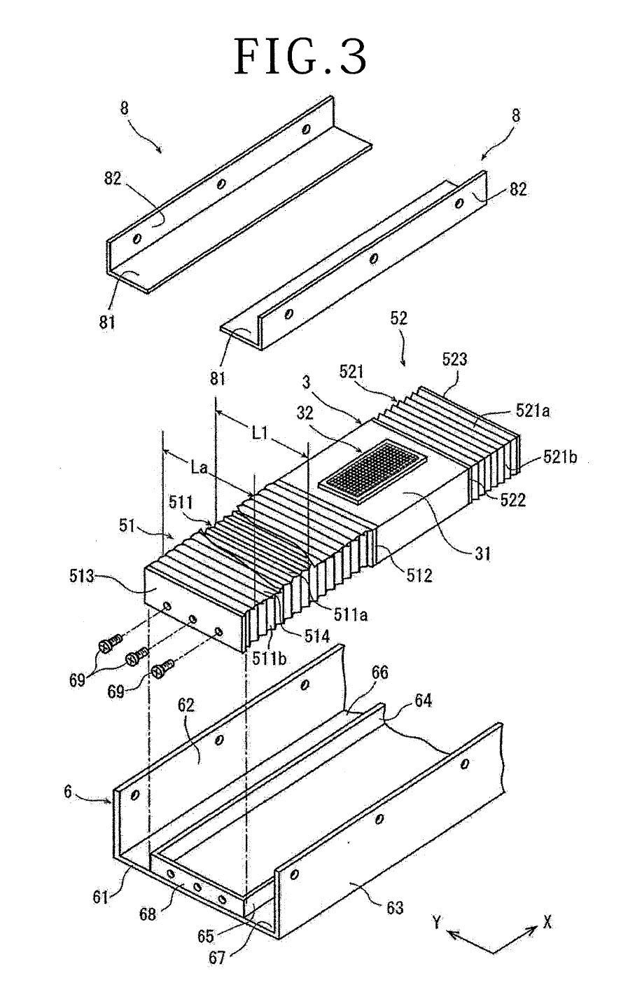

Each of the plural protective plate members 514 is formed of synthetic resin such as polyester or metal such as aluminum alloy. As shown in FIG. 3, each protective plate member 514 has a length La greater than or equal to a width L1 of the bellows member 511 in the Y direction. Further, as shown in FIG. 4A, each protective plate member 514 has a width Lb greater than a spacing L2 between the adjacent ridges of the bellows member 511 in its most expanded condition in the X direction. The plural protective plate members 514 are mounted on the plural ridges of the bellows member 511 in such a manner that one side edge of each protective plate member 514 in the X direction (the right side edge as viewed in FIGS. 4A and 4B), i.e., one side edge of each protective plate member 514 on the side where the holding table 3 as a moving member is located, is bonded to the corresponding ridge of the bellows member 511. The bellows member 511 is expanded and contracted between the expanded condition shown in FIG. 4A and the contracted condition shown in FIG. 4B. In concert with this expansion and contraction of the bellows member 511, each protective plate member 514 provided on the upper side of the bellows member 511 is allowed to slide on the upper surface of its adjacent protective plate member (the adjacent protective member on the left side of each protective plate member as viewed in FIGS. 4A and 4B), so that each protective plate member 514 does not interfere with the expansion and contraction of the bellows member 511. Accordingly, the upper wall 511a of the bellows member 511 is always covered with the plural protective plate members 514, so that there is no possibility that scraps generated from the workpiece in cutting the workpiece by using the cutting blade 43 may enter the grooves of the bellows member 511. Accordingly, it is possible to prevent damage to the bellows member 511 due to the scraps mentioned above.

Each of the plural protective film members 515 provided between the plural protective plate members 514 and the bellows member 511 is formed of a flexible material such as polyurethane elastomer. Each protective film member 515 has substantially the same length as the length La of each protective plate member 514 in the Y direction. Each protective film member 515 is mounted in such a manner that one side edge of each protective film member 515 in the X direction is bonded to the lower surface (back side) of the corresponding protective plate member 514 at its central portion in the X direction and that the other side edge of each protective film member 515 is bonded to the corresponding ridge of the bellows member 511 on which its adjacent protective plate member 514 (the adjacent protective plate member 514 on the left side of each protective plate member 514 as viewed in FIGS. 4A and 4B) is mounted. The width of each protective film member 515 in the X direction is set to a value allowing the expansion of the bellows member 511 up to the most expanded condition shown in FIG. 4A. When the bellows member 511 is contracted as shown in FIG. 4B, each protective film member 515 is flexibly bent along the lower surface (back side) of the corresponding protective plate member 514. Even if the scraps may pass between the adjacent protective plate members 514 overlapped, the entry of the scraps into the grooves of the bellows member 511 can be prevented by the protective film members 515.

As similar to the first bellows 51, the second bellows 52 is composed of a bellows member 521 adapted to be expanded and contracted and a pair of connecting members 522 and 523 mounted on both ends of the bellows member 521 in the X direction. However, the second bellows 52 has no protective plate members and no protective film members. The bellows member 521 is formed from a foldable sheet member like a cloth so as to have a plurality of alternate ridges and grooves. The bellows member 521 has an upper wall 521a and a pair of opposite side walls 521b connected to the upper wall 521a. Each of the connecting members 522 and 523 may be formed from a metal plate. The second bellows 52 configured above is mounted in such a manner that the connecting member 522 is connected to the other end surface of the holding table 3 and the connecting member 523 is connected to another stationary member (not shown).

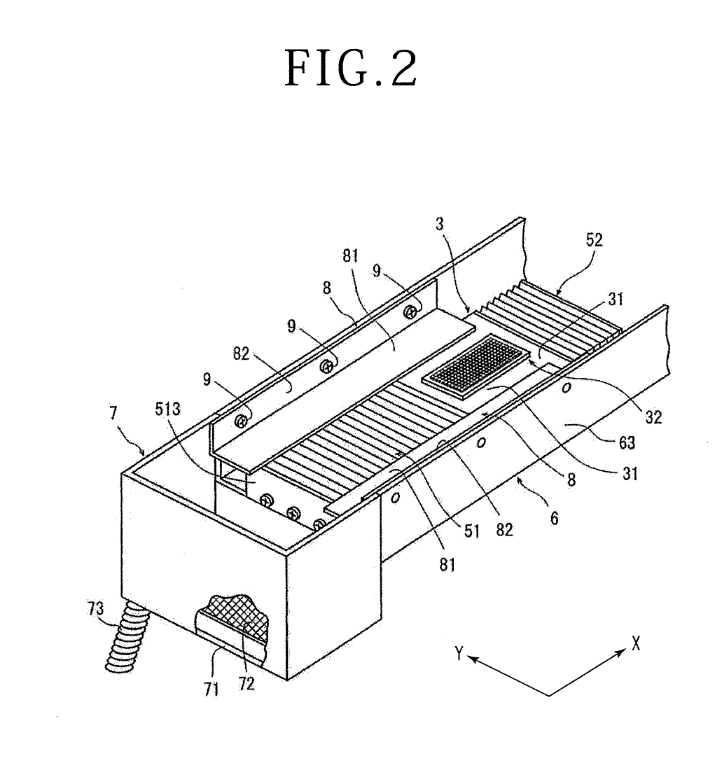

Referring again to FIGS. 2 and 3, a partition member 6 is provided so as to cover the lower side and opposite sides (in the Y direction) of the holding table 3, the first bellows 51, and the second bellows 52. The partition member 6 has a bottom wall 61 for covering the lower side of the holding table 3, the first bellows 51, and the second bellows 52 and a pair of opposite side walls 62 and 63 extending upward from the opposite side edges of the bottom wall 61. As shown in FIG. 3, a pair of partition plates 64 and 65 are mounted on the upper surface of the bottom wall 61 so as to extend parallel to the opposite side walls 62 and 63, respectively. Accordingly, a drain channel 66 is formed by the side wall 62 and the partition plate 64 on the bottom wall 61 of the partition member 6, and another drain channel 67 is formed by the side wall 63 and the partition plate 65 on the bottom wall 61 of the partition member 6. These drain channels 66 and 67 function as a pair of drain channels provided on the opposite sides of the first and second bellows 51 and 52 in the Y direction for receiving a cutting water. The spacing between the partition plate 64 and the partition plate 65 is set to a value smaller than the width L1 of the bellows member 511 of the first bellows 51 (and the width of the bellows member 521 of the second bellows 52). Accordingly, the partition plates 64 and 65 are surrounded by the bellows member 511 of the first bellows 51 and the bellows member 521 of the second bellows 52. A mounting plate 68 as a stationary member is mounted on the downstream ends of the partition plates 64 and 65 so as to connect them together. The connecting member 513 mounted on the bellows member 511 of the first bellows 51 is mounted to the mounting member 68 by means of fastening bolts 69.

Referring again to FIG. 2, scrap receiving means (scrap receptacle) 7 for receiving the scraps is provided on the downstream side of the first bellows 51 in the X direction. The scrap receiving means 7 is connected to the downstream end of the partition member 6. The scrap receiving means 7 has a bottom plate 71, a net 72 provided above the bottom plate 71 at a predetermined distance therefrom, and a drain duct 73 connected to the bottom plate 71.

Referring again to FIGS. 2 and 3, the cutting apparatus 2 according to the preferred embodiment includes a pair of fall prevention plates 8 provided along the drain channels 66 and 67 for preventing that the scraps scattered onto the first bellows 51 may fall into the drain channels 66 and 67. Each of the fall prevention plates 8 is a sectionally L-shaped member composed of a fall preventing portion 81 and a mounting portion 82. One of the fall prevention plates 8 is mounted on the inner surface of the side wall 62 of the partition member 6 in such a manner that the mounting portion 82 is fixed to the side wall 62 by means of fastening bolts 9. Similarly, the other fall prevention plate 8 is mounted on the inner surface of the side wall 63 of the partition member 6 in such a manner that the mounting portion 82 is fixed to the side wall 63 by means of fastening bolts (not shown). One of the fall prevention plates 8 has a length ranging from the downstream end of the drain channel 66 to the holding table 3 in its standby position shown in FIG. 2 where the workpiece is held or upheld. Similarly, the other fall prevention plate 8 has a length ranging from the downstream end of the drain channel 67 to the holding table 3 in its standby position. Further, one of the fall prevention plates 8 is provided above the first bellows 51 in the condition where the mounting portion 81 is mounted on the inner surface of the side wall 62 of the partition member 6, wherein the fall preventing portion 81 has a width covering one side portion of the first bellows 51 in the Y direction. Similarly, the other fall prevention plate 8 is provided above the first bellows 51 in the condition where the mounting portion 82 is mounted on the inner surface of the side wall 63 of the partition member 6, wherein the fall preventing portion 81 has a width covering the other side portion of the first bellows 51 in the Y direction. Accordingly, the fall preventing portions 81 of the fall prevention plates 8 fully cover the drain channels 66 and 67. In the preferred embodiment, each fall prevention plate 8 is formed of fluororesin superior in lubricity.

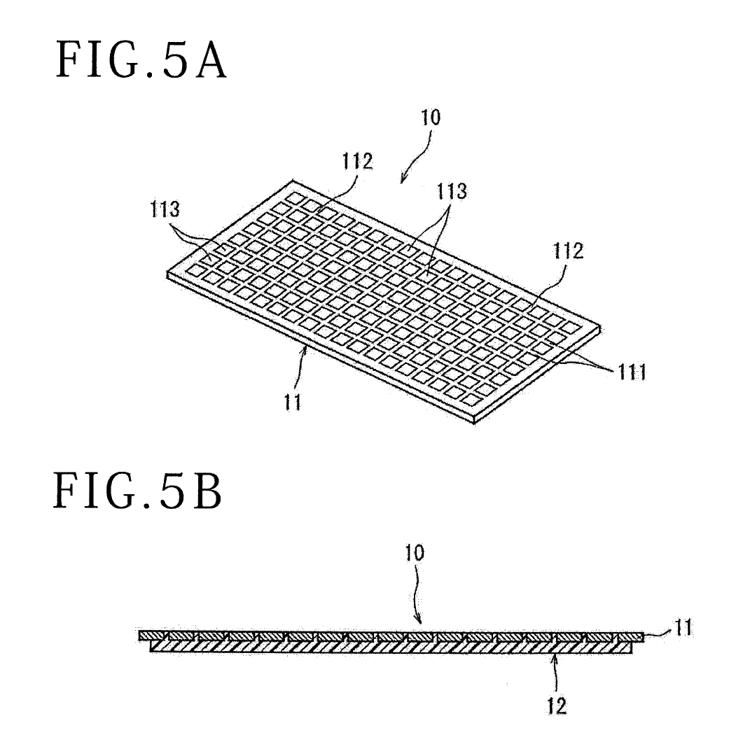

The operation of the cutting apparatus 2 according to the preferred embodiment will now be described. FIG. 5A is a perspective view of a package substrate 10 as a workpiece to be cut by the cutting apparatus 2, and FIG. 5B is a sectional view of the package substrate 10. The package substrate 10 includes a metal plate 11. A plurality of first division lines 111 extending in a first direction and a plurality of second division lines 112 extending in a second direction perpendicular to the first direction are formed on the front side (upper surface) of the metal plate 11. That is, the first division lines 111 intersect the second division lines 112 at right angles on the front side of the metal plate 11, thereby defining a plurality of separate rectangular regions where a plurality of devices (chip size packages) 113 are individually provided. These devices 113 are molded with a synthetic resin portion 12 from the back side (lower surface) of the metal plate 11. The package substrate 10 configured above is cut along the first and second division lines 111 and 112 to thereby obtain the individual devices 113 packaged.

In dividing the package substrate 10 into the individual packaged devices (chip size packages) 113 by using the cutting apparatus 2, the package substrate 10 is first placed on the vacuum chuck 32 of the holding table 3 of the cutting apparatus 2. Thereafter, the suction means (not shown) is operated to hold the package substrate 10 on the vacuum chuck 32 of the holding table 3 under suction (package substrate holding step).

After performing the package substrate holding step, the X moving means (not shown) is operated to move the holding table 3 holding the package substrate 10 to a position directly below the imaging means 45. In the condition where the holding table 3 is positioned directly below the imaging means 45, an alignment operation is performed by the imaging means 45 and the control means (not shown) to detect a subject area of the package substrate 10 to be cut. More specifically, the imaging means 45 and the control means (not shown) perform image processing such as pattern matching for making the alignment between the cutting blade 43 and the first division lines 111 extending in the first direction on the front side of the package substrate 10, thus performing the alignment for the first division lines 111. Similarly, the alignment is performed for the second division lines 112 extending in the second direction perpendicular to the first direction on the front side of the package substrate 10.

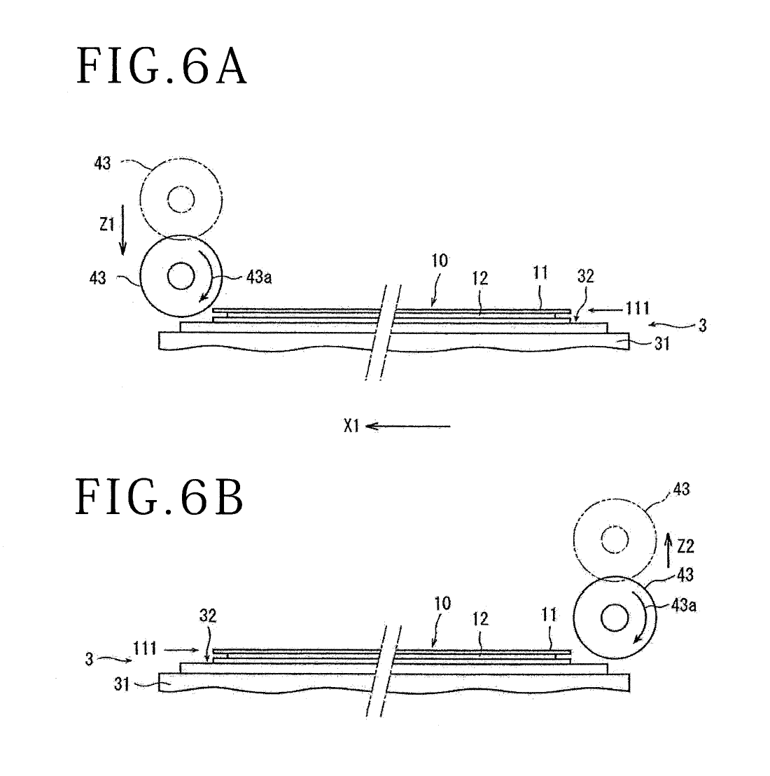

After performing the alignment for detecting the first and second division lines 111 and 112 of the package substrate 10 held on the holding table 3, the holding table 3 is moved to a cutting position where the package substrate 10 is cut by the cutting blade 43. That is, as shown in FIG. 6A, one end (left end as viewed in FIG. 6A) of a predetermined one of the first division lines 111 is positioned on the slightly right side of a position directly below the cutting blade 43 as viewed in FIG. 6A. In this condition, the cutting blade 43 is rotated and the Z moving means (not shown) is operated to lower the cutting blade 43 by a predetermined amount in the direction shown by an arrow Z1 from a retracted position shown by a phantom line to a working position shown by a solid line. At this time, the depth of cut by the cutting blade 43 at the working position is set so that the lower end of the outer circumference of the cutting blade 43 reaches each escape groove (not shown) formed on the vacuum chuck 32 of the holding table 3. Thereafter, the X moving means (not shown) is operated to move the holding table 3 at a predetermined feed speed in the direction shown by an arrow X1 in FIG. 6A. When the other end (right end as viewed in FIG. 6B) of the predetermined first division line 111 of the package substrate 10 held on the vacuum chuck 32 of the holding table 3 reaches the slightly left side of the position directly below the cutting blade 43 as viewed in FIG. 6B, the movement of the holding table 3 is stopped and the cutting blade 43 is raised in the direction shown by an arrow Z2 from the working position to the retracted position as shown in FIG. 6B. Thereafter, the Y moving means (not shown) is operated to index the cutting blade 43 to the next first division line 111 to repeat the above cutting operation. As a result, the package substrate 10 is cut along all of the first division lines 111 (first cutting step). In performing the first cutting step, the cutting water supplying means (not shown) is operated to supply the cutting water from the cutting water nozzle 44 to the cutting area where the package substrate 10 is cut by the cutting blade 43.

After performing the first cutting step, the holding table 3 is rotated 90 degrees to make the second division lines 112 of the package substrate 10 held on the vacuum chuck 32 of the holding table 3 parallel to the X direction. In this condition, the package substrate 10 is cut along all of the second division lines 112 in a manner similar to that of the first cutting step (second cutting step). Also in performing the second cutting step, the cutting water supplying means (not shown) is operated to supply the cutting water from the cutting water nozzle 44 to the cutting area where the package substrate 10 is cut by the cutting blade 43.

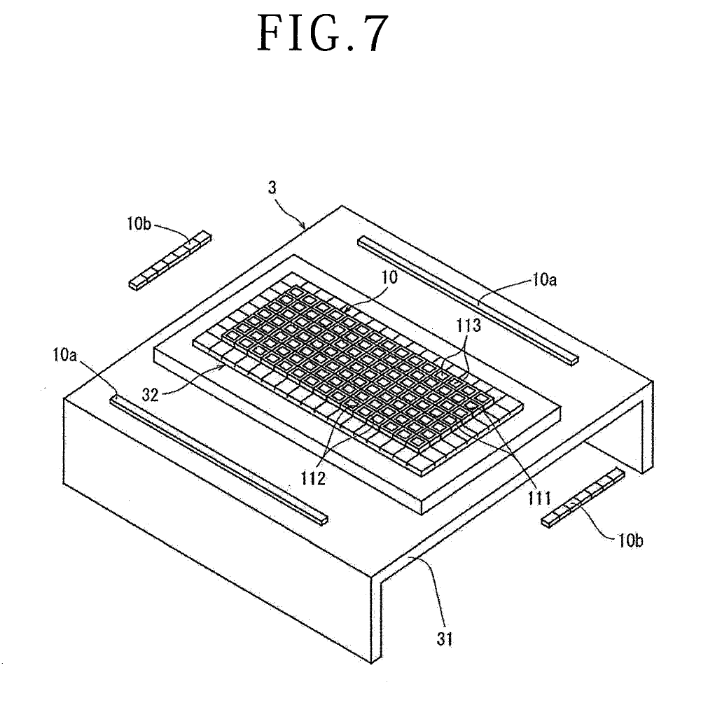

FIG. 7 shows a condition of the package substrate 10 processed by the first cutting step and the second cutting step mentioned above. As shown in FIG. 7, the package substrate 10 is cut along the first division lines 111 and the second division lines 112 to obtain the individual devices (chip size packages) 113. These individual devices 113 are maintained in the condition where they are held on the vacuum chuck 32 under suction. On the other hand, a peripheral marginal area of the package substrate 10 where the devices 113 are not formed is not held on the vacuum chuck 32 under suction, so that this peripheral marginal area is scattered as scraps 10a and 10b in the first and second cutting steps.

In performing the first and second cutting steps, the cutting water supplied from the cutting water nozzle 44 to the cutting area where the package substrate 10 is cut by the cutting blade 43 and the cutting dust generated by the cutting are scattered onto the plural protective plate members 514 covering the upper surface of the bellows member 511 of the first bellows 51 and then allow to fall into the drain channels 66 and 67. The cutting water containing the cutting dust is then allowed to flow into the scrap receiving means 7. Further, the scraps 10a and 10b generated from the package substrate 10 in cutting it by using the cutting blade 43 are also scattered onto the protective plate members 514. The scraps 10a and 10b are also scattered above the drain channels 66 and 67 provided on both sides of the protective plate members 514 in the Y direction.

However, since the fall prevention plates 8 are provided to prevent that the scraps 10a and 10b scattered onto the protective plate members 514 may fall into the drain channels 66 and 67, the scraps 10a and 10b can be received by the fall preventing portions 81 of the fall prevention plates 8. Further, the scraps 10a and 10b scattered above the drain channels 66 and 67 can also be received by the fall preventing portions 81 of the fall prevention plates 8. Accordingly, all of the scraps 10a and 10b thus scattered can be prevented from falling into the drain channels 66 and 67, so that it is possible to solve the problem that the cutting water may stay in the drain channels 66 and 67 due to the accumulation of the scraps 10a and 10b in the drain channels 66 and 67, and as a result the cutting water may overflow from the drain channels 66 and 67 to contaminate the inside of the cutting apparatus 2.

The scraps 10a and 10b received by the fall preventing portions 81 of the fall prevention plates 8 are forced toward the scrap receiving means 7 to fall into the scrap receiving means 7. At this time, since the fall prevention plates 8 are formed of fluororesin superior in lubricity, the scraps 10a and 10b can be easily moved along the fall preventing portions 81. The scraps 10a and 10b that have fallen into the scrap receiving means 7 are received (entrapped) by the net 72 provided near the bottom of the scrap receiving means 7 and then accumulated on the net 72. The scraps 10a and 10b scattered onto the protective plate members 514 are also forced into the scrap receiving means 7 by the movement of the holding table 3 and the protective plate members 514. On the other hand, the cutting water containing the cutting dust that has fallen into the scrap receiving means 7 is allowed to pass through the net 72 and then discharged through the drain duct 73.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A cutting apparatus comprising:
a holding table for holding a workpiece;
cutting means having a cutting blade for cutting said workpiece held on said holding table;
cutting water supplying means for supplying a cutting water to a cutting area where said workpiece is cut by said cutting blade;
feeding means for moving said holding table in a feeding direction;
indexing means for moving said cutting means in an indexing direction perpendicular to said feeding direction;
a first bellows connected at one end thereof to one end of said holding table in said feeding direction, said first bellows having an upper wall and opposite side walls adapted to be expanded and contracted for covering said feeding means;
a second bellows connected at one end thereof to the other end of said holding table in said feeding direction, said second bellows having an upper wall and opposite side walls adapted to be expanded and contracted for covering said feeding means;
a pair of drain channels provided on both sides of said first and second bellows in said indexing direction for receiving said cutting water supplied to said cutting area by said cutting water supplying means in cutting said workpiece;
a scrap receptacle provided at the other end of said first bellows in said feeding direction for receiving scraps generated from said workpiece in cutting said workpiece; and
a pair of fall prevention plates provided along said pair of drain channels for preventing that said scraps scattered onto said upper wall of said first bellows in cutting said workpiece may fall into said drain channels.

2. The cutting apparatus according to claim 1, wherein said fall prevention plates are formed of fluororesin.
